(19) United States
(12) Patent Application Publication
(10) Pub. No.: US 2006/0099445 A1
(43) Pub. Date: May 11, 2006

(54) Organic electro-luminescence device and method of making the same

(75) Inventors: Sherry Lin, Pingtung County (TW); Chun-Chin Chang, Taichung County (TW); Gwo-Sen Lin, Taichung City (TW)

Correspondence Address: BACON & THOMAS, PLLC, 625 SLATERS LANE, FOURTH FLOOR, ALEXANDRIA, VA, 22314, US

(73) Assignee: Wintek Corporation, Taichung (TW)

(21) Appl. No.: 10/982,934

(22) Filed: Nov. 8, 2004

(51) Int. Cl. H01L 51/54; C09K 11/06; H05B 33/14

(52) U.S. Cl. 428/690; 428/917; 313/504; 313/506; 257/102; 257/103; 257/E51.027; 427/66

(57) ABSTRACT

An electro-luminescence device has an anode and a cathode, between which a hole transporting layer, an emitting layer and a hole insulating layer are provided. The emitting layer is made of a material including a light emitting material of polymer doped with two light emitting materials of molecule. A method of making the electro-luminescence applies the wet process to make the hole insulating layer and the emitting layer to simplify the steps and to control the factors of fabrication.

### BACKGROUND OF THE INVENTION

1. Field of the Invention

The present invention relates generally to an illuminating device, and more particularly to an organic electro-luminescence device that provides with light and the method of making the same.

2. Description of the Related Art

FIG. 1 shows a conventional electro-luminescence device 1 for providing with light, which has an anode 2 and a cathode 3, between which three organic layers 4a, 4b and 4c are provided. The organic layers 4a, 4b and 4c are made of different light emitting materials and are activated by a bias voltage provided by the anode 2 and the cathode 3 to emit red light, green light and blue light. While the red light, green light and blue light have substantially identical luminance, it will get white light.

The illumination efficiency and life of the organic layers 4a, 4b and 4c are different, for example, the red light organic layer has a shorter life than the other that reduces the total life of the electro-luminescence device 1. The driving voltages of the organic layers 4a, 4b and 4c are different as well that makes the electro-luminescence device 1 difficult in fabrication and in control.

As shown in FIG. 2, another conventional electro-luminescence device 5 has a first main layer 6, which is made of DPVBi, and a second main layer 7, which is made of CBP, to emit light. The first main layer 6 is doped with DSA, which emits blue light, and the second main layer 7 is doped with Ir(ppy)₃, which emits green light, and DCM2, which emits red light. The electro-luminescence device 5 also has an anode and a cathode to provide a bias voltage to the layers 5 and 7, such that the layers 5 and 7 emits red light, green light and blue light respectively and the mix of the lights is white light.

However, the layers 5 and 7 of the electro-luminescence device 5 is made of a molecule material and hole/electron transporting layers 8 and 9 is made of a molecule material, such as CuPc/Alq3, as well, so that the best method to fabricate them is the vacuum evaporation process. For the vacuum evaporation process, it is hard to control the concentrations of the doped organic molecules and the procedures thereof are complex as well.

### SUMMARY OF THE INVENTION

The primary objective of the present invention is to provide a method of making an electro-luminescence device, which has simpler procedures and the factors of fabrication are easier to control.

The secondary objective of the present invention is to provide an electro-luminescence device, which has lower voltage input and higher luminance output.

The third objective of the present invention is to provide an electro-luminescence device, which provides a stable white light and the light has a well white chroma.

According to the objectives of the present invention, an electro-luminescence device has an anode, a cathode and an emitting layer between the anode and the cathode. The emitting layer is made of a material, which has a light emitting material of polymer doped with at least a light emitting material of molecule.

A method of making the electro-luminescence device has fabrication of an anode on a substrate. Provide a hole transporting layer on the anode by a wet process. The hole transporting layer is an organic solution of a polymer material. Provide an emitting layer on the hole transporting layer by a wet process. The emitting layer has a host with a light emitting material of polymer and a dopant with at least a light emitting material of molecule and the host and the dopant are melted in an organic solvent. Provide a hole insulating layer on the emitting layer to restrict holes in the emitting layer. Provide an electron injection layer on the hole insulating layer, wherein the electron injection layer is made of a molecule material, and provide a cathode on the electron injection layer.

### BRIEF DESCRIPTION OF THE DRAWINGS

FIG. 1 is a sectional view of a conventional electro-luminescence device;

FIG. 2 is a sectional view of another conventional electro-luminescence device;

FIG. 3 is a flowchart of the method of a preferred embodiment of the present invention;

FIG. 4 is a sectional view of the device of the preferred embodiment of the present invention;

FIG. 5 is a diagram showing the wavelength distribution of the white light emitted from the device of the present invention, and

FIG. 6 is a wavelength-transmittance diagram, in which the color filter film is introduced in the device of the present invention.

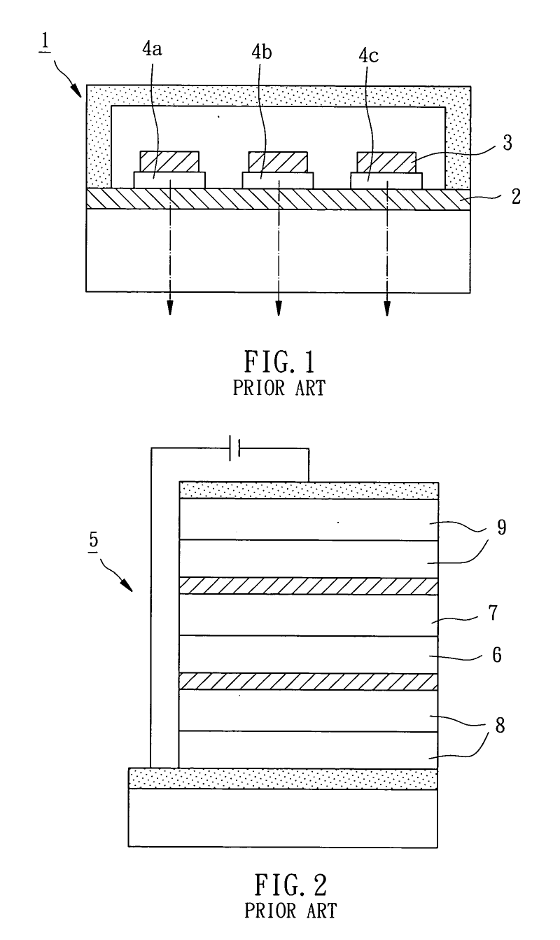

### DETAILED DESCRIPTION OF THE INVENTION

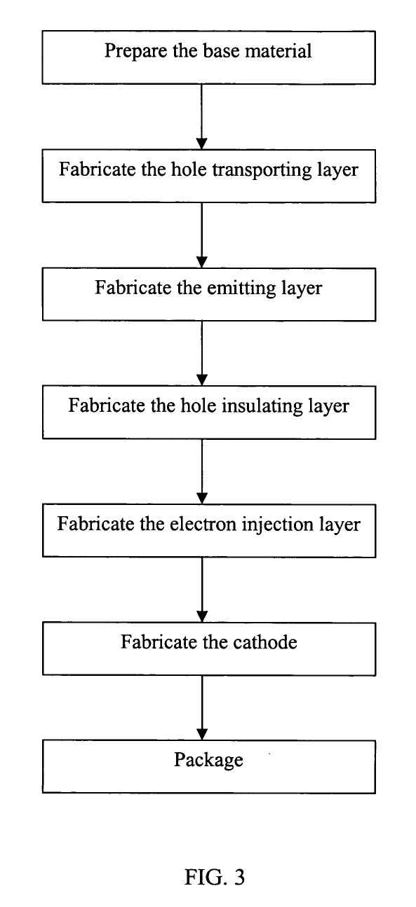

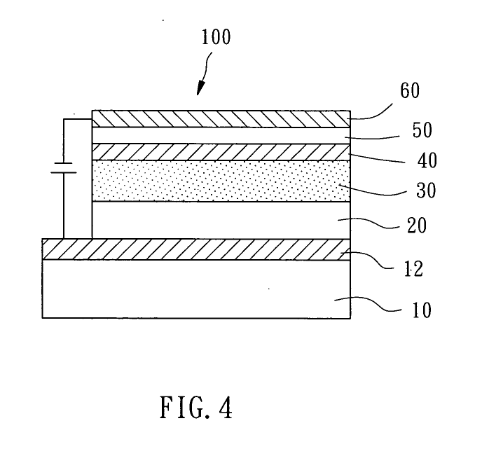

As shown in FIG. 3 to FIG. 4, a method of making an electro-luminescence device 100 of the preferred embodiment of the present invention comprises the steps of:

Prepare a base material:
Provide an anode 12 on a top of a substrate 10, wherein the substrate 10 is made of glass, flexible plastic, conductive metal or organic material and the anode 12 is made of a material chosen from indium tin oxide (ITO), indium zinc oxide (IZO) and aluminum zinc oxide (AZO) and a thickness of the anode 12 is between 1000 Å and 6000 Å.

Fabrication of a hole transporting layer 20:
Melt polymer, such as PEDOT and polyaniline, in an organic solvent to form an organic solution. And then, coat the solution onto the substrate 10 by a spin coating method of a wet process. And then, bake the substrate 10 in a chamber filled with idle gas to form a film with a thickness between 5 Å and 2500 Å. In the preferred embodiment of the present invention, PEDOT is doped with PSS that increase the efficiency of hole injection. The hole transporting layer 20 preferably has a thickness between 20 Å and 700 Å. The wet process includes ink inject printing method, roller coating method, screen printing method, doctor blade coating method and thermoprinting method and so on.

Fabrication of an emitting layer 30:
Provide a light emitting material of polymer to be a host and two light emitting materials of molecule to be dopants. The host and the dopants are mixed in an organic solvent, such as xylene, CH₂Cl₂ or THF, and then is coated onto the hole transporting layer 20 by a wet process, and then is baked in a chamber filled with idle gas to form a film with a thickness between 5 Å and 2500 Å. The wet process mentioned here is the spin coating method (face-down spinning method). The light emitting material of polymer can be chosen from poly{2,7-[(9,9-di(alkyl)fluorine)}, para-phenylene ethylene (PPV) poly-(N-vinylcarbazole) (PVK) or the Blue J material of DOW Chemical and the emitting material of molecule can be chosen from C545T, Ir(ppy)3, DCJTB, Rubrene or PtOEP.

In the present preferred embodiment, the Blue J material made by DOW Chemical is chosen to be the light emitting material of polymer for emitting of blue light and C545T and DCJTB are chosen to be the light emitting materials of molecule for emitting of green light and red light respectively. A ratio of Blue J, C545T and DCJTB is preferred 1:0.07:0.04 and a thickness of the emitting layer 30 is preferred 300 Å.

Fabrication of a hole insulating layer 40:
Molecule materials, such as BCP and TPBI, or polymer materials, such as F8-TFB, can be provided to make the hole insulating layer 40. In the present preferred embodiment, the hole insulating layer 40 is made of TPBI and is formed on the emitting layer 30 by evaporation or by sputtering with a thickness between 5 Å and 1000 Å to restrict holes in the emitting layer 30. The thickness of the hole insulating layer 40 is preferred 200 Å. While the hole insulating layer 40 is made of polymer material, the evaporation or sputtering of the wet process is introduced to form it on the emitting layer 30.

Fabrication of an electron injection layer 50:
The electron injection layer 50 is made of a molecule material and is formed on the hole insulating layer 40 by evaporation or by sputtering with a thickness between 5 Å and 2000 Å. In the present preferred embodiment, the electron injection layer 50 is made of Alq.

Fabrication of a cathode 60:
The cathode 60 is formed on the electron injection layer 50 by evaporation or by sputtering with a thickness between 1000 Å and 5000 Å. The cathode 60 can be a single layer or multi-layers. The material of the cathode 60 of single layer is chosen from aluminum (Al) or silver (Ag) and the materials of cathode 60 of multi-layers are chosen from calcium (Ca)/aluminum (Al), barium (Ba)/aluminum (Al), calcium (Ca)/alloy of magnesium and aluminum (Mg:Al) and barium (Ba)/alloy of magnesium and aluminum (Mg:Al). In the present preferred embodiment, the cathode 60 is made of Ca/Al alloy and a thickness of Ca is preferred 400 Å and a thickness of Al is preferred 1000 Å.

The electro-luminescence device 100 of the present invention is packaged after aforesaid steps to isolate water and air, which might cause the anode and the cathode of the device 100 oxidized, and to shield the organic layers to keep them working normally. A desiccant film (not shown) is provided to the device 100 in the package process to enhance the property of preventing oxidation.

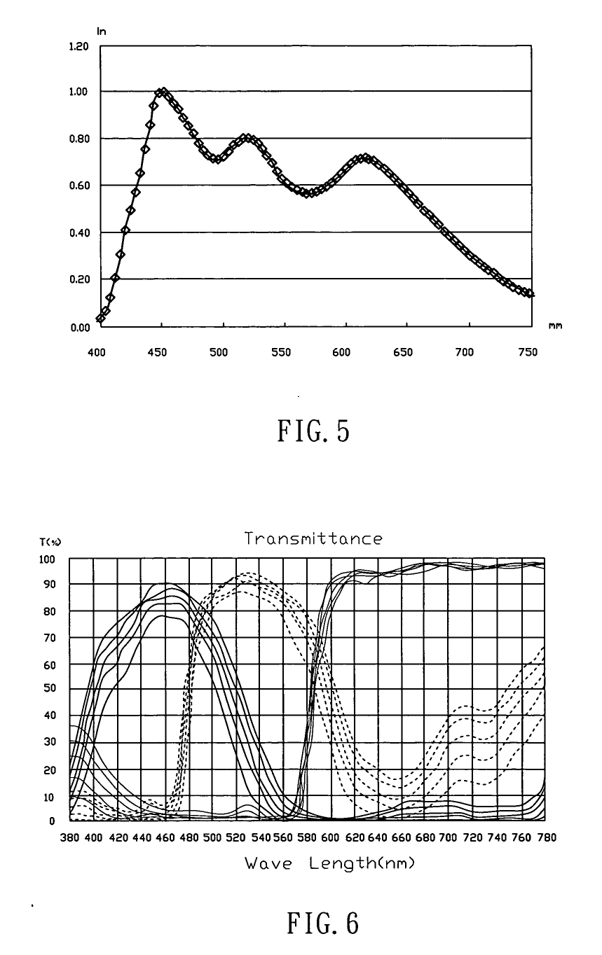

A bias voltage (10V, 50 mA/cm²) is added to the anode 12 and the cathode 60 of the device 100 of the present invention to recombine the holes and the electrons in the emitting layer 30, which is made of a mixture of molecule and polymer with a predetermined ratio, and to activate the Blue J emitting blue light as well as the C545T and the DCJTB emitting green light and red light respectively. As shown in FIG. 5, the blue light, the green light and the red light are mixed to get white light with continuous full-wavelength as well as the properties of three wavelengths. The CIE coordinates of the white light is x=0.30 and y=0.33, which has a well performance of pure white light. The electro-luminescence device 100 of the present invention has a luminance of 6500 cd/cm². The device 100 of the present invention is driven by a lower voltage, which provides a higher driving power of 5.61 m/w.

In conclusion, the wet process is applied in the process of fabrication of the hole transporting layer and the emitting layer of the electro-luminescence device 100 of the present invention, which has the advantages of simplification of the steps and control of the factors that affects the fabrication, such as the doped concentration of the organic material in the evaporation process. The device 100 of the present invention provides the white light independent to the variety of the driving voltage, it is stable.

The emitting layer 30 of the present invention is consisted of the light emitting material of polymer doped with two of the light emitting materials of molecule, which the light emitting materials of molecule provide complementary lights respectively. While the emitting layer 30 emits the white light, the white light has continuous full-wavelength and has three peaks in a wavelength (referring to FIG. 5). Each of the peaks is associated with the transmittance of the color filter film (referring to FIG. 6). As a result, the combination of the electro-luminescence device 100 of the present invention and the color filter film completes a color display panel.

The description above is a preferred embodiment of the present invention and the equivalence of the present invention is still in the scope of the claim of the present invention.

What is claimed is:

1. An electro-luminescence device, comprising an anode, a cathode and an emitting layer between the anode and the cathode, wherein the emitting layer is made of a material, which has a light emitting material of polymer doped with at least a light emitting material of molecule.

2. The electro-luminescence device as defined in claim 1, wherein a ratio of the light emitting material of polymer and the light emitting material of molecule is between 1:0.0001 and 1:0.1.

3. The electro-luminescence device as defined in claim 1 wherein a thickness of the emitting layer is between 5 Å and 2500 Å.

4. The electro-luminescence device as defined in claim 1, wherein the light emitting material of polymer is chosen from poly{2,7-[(9,9-di(alkyl)fluorine)], para-phenylene ethylene (PPV) and poly-(N-vinylcarbazole) (PVK).

5. The electro-luminescence device as defined in claim 1, wherein the light emitting material of molecule is chosen from C545T, Ir(ppy)3, DCJTB, Rubrene and PtOEP.

6. The electro-luminescence device as defined in claim 1, further comprising a hole transporting layer between the anode and the emitting layer, which is made of polymer.

7. The electro-luminescence device as defined in claim 1, further comprising an electron injection layer between the anode and the emitting layer, which is made of a molecule material.

8. The electro-luminescence device as defined in claim 7, further comprising a hole insulating layer between the electron injection layer and the emitting layer.

9. A method of making an electro-luminescence device, comprising the steps of:
providing an anode on a substrate;
providing a hole transporting layer on the anode by a wet process, wherein the hole transporting layer is an organic solution of a polymer;
providing an emitting layer on the hole transporting layer by a wet process, wherein the emitting layer has a host having a light emitting material of polymer and a dopant having at least a light emitting material of molecule and the host and the dopant are melted in an organic solvent;
providing a hole insulating layer on the emitting layer to restrict holes in the emitting layer;
providing an electron injection layer on the hole insulating layer, wherein the electron injection layer is made of a molecule material, and
providing a cathode on the electron injection layer.

10. The method as defined in claim 9, wherein the light emitting material of polymer is chosen from poly{2,7-[(9,9-di(alkyl)fluorine)], para-phenylene ethylene (PPV) and poly-(N-vinylcarbazole) (PVK) and the light emitting material of molecule is chosen from C545T, Ir(ppy)3, DCJTB, Rubrene and PtOEP.

11. The method as defined in claim 9, wherein a ratio of the light emitting material of polymer and the light emitting material of molecule is between 1:0.0001 and 1:0.1.
